(19) United States
(12) Patent Application Publication
(10) Pub. No.: US 2023/0187341 A1
(43) Pub. Date: Jun. 15, 2023

(54) BARRIER LINER FREE INTERFACE FOR METAL VIA

(71) Applicant: INTERNATIONAL BUSINESS MACHINES CORPORATION, Armonk, NY (US)

(72) Inventors: Nicholas Anthony Lanzillo, Wynantskill, NY (US); Koichi Motoyama, Clifton Park, NY (US); Chanro Park, Clifton Park, NY (US); Kenneth Chun Kuen Cheng, Shatin (HK)

(21) Appl. No.: 17/546,682

(22) Filed: Dec. 9, 2021

(51) Int. Cl. H01L 23/522; H01L 21/768; H01L 23/532

(52) U.S. Cl. CPC H01L 23/5226; H01L 21/76834; H01L 21/76832; H01L 21/76877; H01L 23/53295

(57) ABSTRACT

An electrical communication structure that includes a plurality of metal line levels, a first metal line in a first metal line level of the plurality of line levels, and a second metal line in an upper metal line level of the plurality of line levels. A base of the second metal line is atop a metal etch stop layer that is aligned with edges of the second metal line. The electrical communication structure further includes a via that extends from the first metal line to the second metal line through the plurality of line levels. the via is not in electrical communication with at least one an intermediate metal line within the plurality of line levels between the first metal line level and the upper metal line level. The via has a metal fill that is in direct contact with a metal fill of the first metal line.

### BACKGROUND

The present disclosure relates to interconnects for transmitting electrical signal, and more particularly to metal vias.

Interconnects are the wiring schemes in integrated circuits, which may be formed during back-end-of-line (BEOL) processing. Interconnects can distribute clock and other signals, provide power and ground for various electronic system components, and interconnect the transistors within the integrated circuit (IC) chip front-end-of-line (FEOL). Interconnects are organized in different metal layers, local (Mₓ), intermediate, semi-global and global wires. The total number of layers can be as many as 15, while the typical number of Mₓ layers ranges between 3 and 6. Each of these layers contains (unidirectional) metal lines (or tracks) and dielectric materials. They are interconnected vertically by means of via structures that are filled with metal. Since its introduction in the mid 1990's, Cu dual damascene in combination with low-k dielectrics, and has been the workhorse metal for lines and vias, in both logic and memory chip applications.

### SUMMARY

A method of forming vias, e.g., skip vias or super vias, that provides a low resistance interface between the via and the metal line in the first metal line level. In one embodiment, the method of forming an electrical communication structure includes forming a metal etch stop layer in a material stack that includes a plurality of metal line levels, wherein a first metal line is present in the first metal line level of the plurality of metal line levels. The method may further include forming a via opening extending though the material stack to the first metal line in the first metal line level; and forming a trench in communication with the via opening in a dielectric layer of the material stack present on the metal etch stop layer. A barrier liner may then be formed on the via and the trench. Horizonal portions of the barrier liner are removed at an interface of the via opening and the first metal line level, and are removed from the metal etch stop layer in the trench. The method may further include filling the via opening and the trench with a metal fill, the metal fill in the via opening in direct contact with the first metal line, and the metal fill within the trench provides a second metal line in direct contact with the metal etch stop layer.

In another aspect, an electrical communication structure is provided that includes vias, e.g., skip vias or super vias, which have a low resistance interface free of barrier layers to a metal line. In one embodiment, the electrical communication structure includes a plurality of metal line levels; a first metal line in a first metal line level of the plurality of line levels; and a second metal line in an upper metal line level of the plurality of line levels. In some embodiments, a base of the second metal line is atop a metal etch stop layer that is aligned with edges of the second metal line. The electrical communication structure can also include a via that extends from the first metal line to the second metal line through the plurality of line levels. The via is not in electrical communication with at least one intermediate metal line within the plurality of line levels between the first metal line level and the upper metal line level. The via includes a metal fill that is in direct contact with a metal fill of the first metal line.

In another embodiment, the electrical communication structure includes a low resistance liner between the via and the metal line. In one embodiment, the electrical communication structure includes a plurality of metal line levels; a first metal line in a first metal line level of the plurality of line levels; and a second metal line in an upper metal line level of the plurality of line levels, wherein a base of the second metal line is atop a metal etch stop layer that is aligned with edges of the second metal line. The electrical communication structure further includes a via extending from the first metal line to the second metal line through the plurality of line levels, wherein the via is not in electrical communication with an intermediate metal line within the plurality of line levels between the first metal line level and the upper metal line level. The via further includes a low resistance liner at an interface of a via metal fill for the via and a metal line fill for the first metal line.

### BRIEF DESCRIPTION OF DRAWINGS

FIG. 1 is a side cross-sectional view of a skip via, in which there is no barrier/liner at the via base where the via contacts a metal line within a first metal line layer (Mx), in accordance with one embodiment of the present disclosure.

FIG. 2 is a side cross-sectional view of an initial structure including three metal line levels having a first region that is subsequently processed to include a via that does not include a barrier/liner at the base of the via where the via contacts a metal line within a first metal line layer of the structure, in accordance with one embodiment of the present disclosure.

FIG. 3 is a side cross-sectional view illustrating one embodiment of forming an upper via opening to the uppermost metal line in a second region of the initial structure depicted in FIG. 2.

FIG. 4 is a side cross-sectional view illustrating one embodiment of patterning the via opening for the via, e.g., super via or skip via, to the first metal line in the first region of the initial structure.

FIG. 5 is a side cross-sectional view depicting forming the trench for an upper metal line that is formed atop a metal etch stop layer, in accordance with one embodiment of the present disclosure.

FIG. 6 is a side cross-sectional view depicting a removing a trench hardmask and removing the portion of the barrier liner that is atop the first metal line in the first metal line level, in accordance with one embodiment of the present disclosure.

FIG. 7 is a side cross-sectional view depicting one embodiment of depositing a barrier liner and seed liner on the sidewalls and base of the trench and the sidewalls and base of the vias, in accordance with one embodiment of the present disclosure.

FIG. 8 illustrates one embodiment of a barrier liner and/or adhesion liner etch back process, in accordance with one embodiment of the present disclosure.

FIG. 9 is a side cross-sectional view depicting a metal fill being applied to the trench and via openings, in accordance with one embodiment of the present disclosure.

FIG. 10 is a side cross-sectional view illustrating removing the portion of the metal etch stop layer that extends across the structure beyond the ends of the metal line, in accordance with one embodiment of the present disclosure.

FIG. 11 is a side cross-sectional view illustrating a dielectric back fill process applied to FIG. 10 followed by planarization.

FIG. 12 is a side-cross sectional view illustrating another embodiment for forming a super via or skip via that includes forming a barrier liner on the sidewalls and base of the via opening to the first metal line.

FIG. 13 is a side-cross sectional view illustrating a barrier etch back process for removing the barrier liner from the horizontally oriented surfaces of the structure depicted in FIG. 12.

FIG. 14 is a side-cross sectional view illustrating a low-resistance liner being deposited in the via openings and the trench followed by forming a fill material for the vias and the metal line.

FIG. 15 is a side-cross sectional view illustrating removing the portion of the metal etch stop layer that extends across the structure beyond the ends of the metal line.

FIG. 16 is a side-cross sectional view illustrating a dielectric back fill process applied to FIG. 15 followed by planarization.

### DETAILED DESCRIPTION OF PREFERRED EMBODIMENTS

Detailed embodiments of the claimed structures and methods are disclosed herein; however, it is to be understood that the disclosed embodiments are merely illustrative of the claimed structures and methods that may be embodied in various forms. In addition, each of the examples given in connection with the various embodiments are intended to be illustrative, and not restrictive. Further, the figures are not necessarily to scale, some features may be exaggerated to show details of particular components. Therefore, specific structural and functional details disclosed herein are not to be interpreted as limiting, but merely as a representative basis for teaching one skilled in the art to variously employ the methods and structures of the present description. For purposes of the description hereinafter, the terms “upper”, “lower”, “right”, “left”, “vertical”, “horizontal”, “top”, “bottom”, and derivatives thereof shall relate to the embodiments of the disclosure, as it is oriented in the drawing figures. The terms “present on” means that a first element, such as a first structure, is present on a second element, such as a second structure, wherein intervening elements, such as an interface structure, e.g. interface layer, may be present between the first element and the second element. The term “direct contact” means that a first element, such as a first structure, and a second element, such as a second structure, are connected without any intermediary conducting, insulating or semiconductor layers at the interface of the two elements.

CMOS technology node scaling has required the dimensional reduction of the back-end-of-line (BEOL) structures, leading to reduced interconnect metal pitches. However, the downscaling of device dimensions with increasing smaller technology node is becoming increasingly challenging. This is mainly due to electrostatic limitations in the front-end-of-line, and to routing congestion and a dramatic RC delay in the back-end-of-line. The RC delay results from a reduced cross-sectional area of the metal wires which drives up the resistance-capacitance product (RC) of the interconnect system. This, in turn, results in strongly increasing signal delay.

One way to cope with these challenges is to introduce design-technology co-optimization (DTCO) complementary to the classical dimensional scaling.

Scaling boosters, such as self-aligned gate contact or buried power rail, enable a reduction of the number of tracks (or M2 pitch, as indicated in the figure below) thereby reducing cell height of a standard logic cell. One of the newcomers in the scaling boosters family is a dual-damascene compatible super via. The term “super via” denotes a high-aspect-ratio via that provides direct connection from a first metal layer (Mₓ) to an upper metal layer, e.g., Mₓ₊₂ metal layer, by bypassing an intermediate metal layer, e.g., Mₓ₊₁ layer. A via that is connects two metal layers on different levels, while skipping connectivity to an intermediate metal layer that is positioned therebetween, can be referred to as a “skip” via. The connectivity of the vias to the metal lines can be by a self-aligned manner. In a Super Via, the aspect ratios can reach 13 or higher. For example, skip level vias, i.e., super vias, can have an aspect ratio of 100. Forming vias with these aspect rations using subtractive methods, such as reactive ion etching (RIE) can result in a very small critical dimension, as the base of the via.

In addition to small critical dimensions at the base of the via, the presence of barrier layer and liners at the bottom of the via can increase the resistance of the via. This can negatively impact performance. For example, with increasing scaling to shrink the cell size from 144 nm to 120 nm by integration of super vias, a resistivity of less than 100Ω is advantageous for device performance.

It has been determined that prior attempts to remove barrier/liner metals at the base of the via which interfaces with the first metal line (Mₓ) an also remove the barrier/liner metals from the portions of the via's at the higher levels, e.g., Mₓ₊₂, of the structure, which results in a reduction of device reliability.

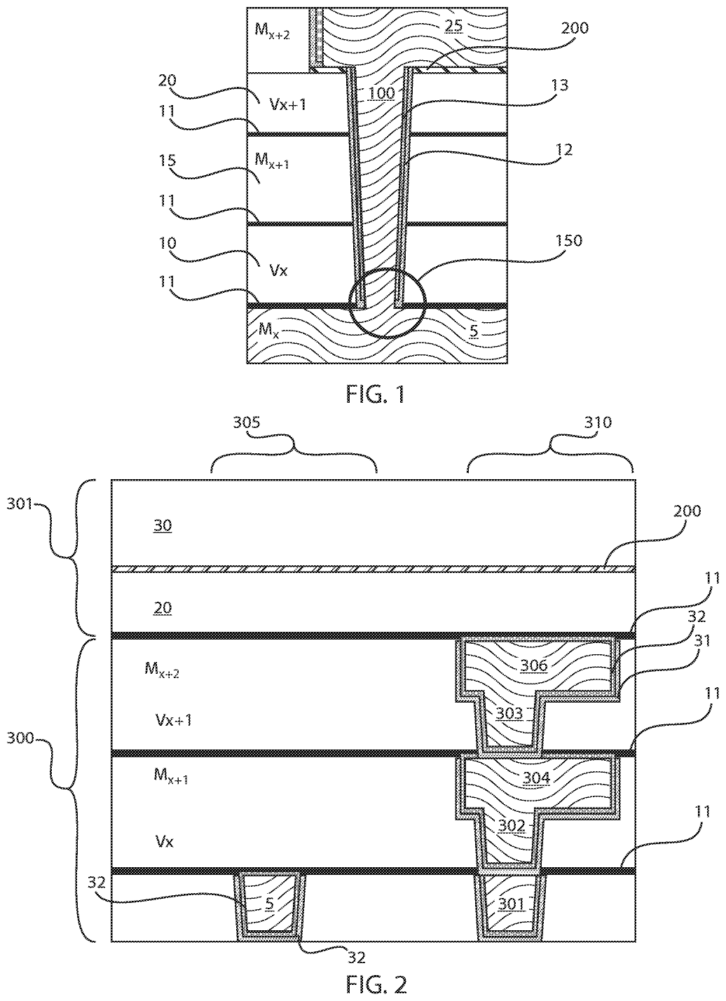

The methods, system and computer program products of the present disclosure can fabricate skip vias without having a barrier layer/barrier liner at the interface of the via base and the first metal line (Mx), and without exposing copper (Cu) conductor to lo-k dielectric at the base of the trenches at the upper metal layers, e.g., Mₓ₊₂, and higher. In some embodiments, the methods, systems and computer program products of the present disclosure introduce a layer of metallic etch stop at the trench bottom for the upper metal layers, e.g., Mₓ₊₂, which can protect the dielectric from exposure to the copper (Cu) conductor. The method and structures for fabricating skip vias with liner/barrier free interfaces at the via base are now described in more detail with reference to FIGS. 1-16.

FIG. 1 is a side cross-sectional view of a skip via, e.g., super via, in which there is no barrier/liner at the via base (bottom) where the via contact the first metal line layer (Mₓ), and there is an etch stop layer on the horizontal surfaces of the dielectric underlying the metal lines in the upper metal line levels (metal level of Mₓ₊₂ and greater). The etch stop layer is a metallic etch stop layer. The presence of the etch stop layer can act as a barrier to separate the metal from the metal lines and dielectric from the interlevel/intralevel dielectric layers, which prevents from the metal from the metal lines from diffusing into the dielectric. For example, when the metal in the metal lines for the upper metal layer (Mₓ₊₂) is copper (Cu), a metallic etch stop layer of tantalum nitride (TaN) can act as a barrier to separate the copper and the dielectric, and to prevent the copper from diffusing into the dielectric.

In the embodiment depicted in FIG. 1, there are three metal levels, e.g., the first metal line level (Mₓ), a second metal line level (Mₓ₊₁) and a third metal line level (Mₓ₊₂). Between each of the metal line levels (Mₓ, Mₓ₊₁ and Mₓ₊₂) is a via dielectric level (V_{X}). For example, a first via level (V_{X}) is positioned between the first metal line level (Mx) and the second metal line level (Mₓ₊₁); and a second via level (Vₓ₊₁) is positioned between the second metal line level (Mₓ₊₁) and a third metal line level (Mₓ₊₂).

The via 100 extends from the metal line 5 in the first metal line level (Mₓ) to the metal line 25 in the third metal line level (Mₓ₊₂), and the via 100 is in direct contact with both the metal line 5 in the first metal line level (Mₓ) and the metal line 25 in the third metal line level (Mₓ₊₂). The via 100 is a “skip via”. A skip via is not in contact with at least one metal line that is present in an intermediate metal line level that the via passes through in making electrical communication to metal lines in the a metal line level above the intermediate line level and a metal line level below the intermediate line level. For example, in the example depicted in FIG. 1, the via 100, e.g., skip via, is not in contact with a metal line that may be present in the second metal line level (Mₓ₊₁), however the via 100 passes through the entirety of the dielectric material in the second metal line level between the metal line 5 in the first metal line level (Mₓ) and the metal line 25 in the third metal line level (Mₓ₊₂). It is noted that this example only illustrates one embodiment of the present disclosure, as any number of metal line levels may be present between the metal line levels including metal lines that are interconnected by a skip via.

The metal line levels and the via line levels may include dielectric material that has been patterned and etched to provide the trenches for the metal lines and the openings for the via's. The compositions of the dielectric material layers 10, 15, 20, 30 may be any suitable dielectric material such as silicon oxide, silicon nitride, hydrogenated silicon carbon oxide, low-k dielectrics, ultralow-k dielectrics, flowable oxides, porous dielectrics, or organic dielectrics including porous organic dielectrics. Low-k dielectric materials have a nominal dielectric constant less than the dielectric constant of SiO₂, which is approximately 4 (e.g., the dielectric constant for thermally grown silicon dioxide can range from 3.9 to 4.0). In one embodiment, low-k dielectric materials may have a dielectric constant of less than 3.7. Suitable low-k dielectric materials include, for example, fluorinated silicon glass (FSG), carbon doped oxide, a polymer, a SiCOH-containing low-k material, a non-porous low-k material, a porous low-k material, a spin-on dielectric (SOD) low-k material, or any other suitable low-k dielectric material. Ultra low-k (ULK) dielectric materials have a nominal dielectric constant less than 2.5. Suitable ultra low-k dielectric materials include, for example, SiOCH, porous pSiCOH, pSiCNO, carbon rich silicon carbon nitride (C-Rich SiCN), porous silicon carbon nitride (pSiCN), boron and phosporous doped SiCOH/pSiCOH and the like.

In one example, the dielectric composition for the dielectric layers 10, 15, 20, 25 may be carbon doped silicon glass (SiCOH) having a dielectric constant ranging from 2.2 to 3.0.

In some embodiments, a dielectric cap 11 may be present between the metal line levels (Mₓ, Mₓ₊₁, Mₓ₊₂) and the via levels (V_{X}, Vₓ₊₁), as depicted in FIG. 1. In one example, the dielectric cap 11 may be composed of silicon carbon nitride (SiCN).

The metal lines 5, 25 may run horizontally across the substrate of the device. For example, the metal lines 5, 25 can run left to right across the page as illustrated in the supplied cross-section depicted in FIG. 1, or the metal lines 5, 25 may run along a plane going into and out of the page. The metal lines 5, 25 may be formed using photolithography and etch processes to pattern trenches, and then filling the trenches with a conductive material, such as a metal, using plating, electroplating, electroless plating, or a deposition process, such as physical vapor deposition, e.g., sputtering. Although an example has been provided above, in which the metal fill is copper (Cu), other metals are equally applicable as the fill for the metal lines 5, 25. In one embodiment, the conductive material includes, for example, Al, W, Cu, Co, Ru, Mo, etc. After depositing the conductive material, metal layer can then be planarized by, for example, a planarization process such as CMP.

The metal lines 5, 25 are connected to the via 100. The via 100 is also formed using photolithography and etch processes similar to the trenches. Similar to the metal lines 5, 25, the via 100 may be filled with copper (Cu). Additionally, copper (Cu) is only one example of a metal fill. In one embodiment, the conductive material for the via 100 includes, for example, Al, W, Cu, Co, Ru, Mo, etc. After depositing the conductive material, metal layer can then be planarized by, for example, a planarization process such as CMP.

The vias 100 may be formed in combination with the metal lines 5, 25 using a single damascene or dual damascene process.

Still referring to FIG. 1, the via structure may further include a barrier liner 12 directly on the sidewalls and the base of the majority of the vias 100 and the dielectrics 10, 15, 20. The barrier layer 12 is composed of a material that obstructs diffusion of the metal from the metal lines 5, 25 and vias 100 into the dielectric material 10, 15, 20, 30 of the metal line levels Mₓ, Mₓ₊₁, Mₓ₊₂, and the via levels Vx, Vₓ₊₁.

The barrier layer 12 may be composed of a metal or metal nitride, such as tantalum (Ta), tantalum nitride (TaN), tungsten nitride (WN), titanium (Ti), titanium nitride (TiN), molybdenum nitride (MoN), tungsten silicon nitride (WSiN), tungsten silicon (WSi), Nb, NbN, Cr, CrN, TaC, TaCeO₂, TaSiN, TiSiN, and combinations thereof.

Directly atop the barrier layer 12 is a seed layer 13. The seed layer 13 present atop the barrier layer 12 can function as an adhesion layer for the deposition of the fill material. In some embodiments, the seed layer 13 is composed of cobalt (Co). The barrier layer 12 and the seed layer 13 may having a conformal thickness.

As noted, in prior methods and structures, a barrier layer 12 and/or seed layer 13 is present at the base of the via 100. The presence of the barrier layer 12 and/or seed layer 13 in combination with the small critical dimension CD (width W1) of the base of the via disadvantageously increases the resistance of prior vias.

However, the vias 100 provided in accordance with the methods, and structures of the present disclosure provide an interface 150 between the base of the via 100 and the upper surface of the metal line 5 that is present in the first metal line level (Mx) that is entirely free of a barrier layer 12 and/or seed layer 13. More specifically, at the interface of the via 100 and the metal line 5, the metal material, e.g., copper, of the via 100, is in direct contact with the metal material, e.g., copper, of the metal line 5 that is present in the first metal line level (Mx).

In prior devices, to provide an interface that is free of barrier material layers at the interface of the base of the via and the metal line, substrative methods are employed to remove the material layers, such as barrier layers and seed layers, from the upper surface of the metal line within the via opening prior to forming the metal fill for the via. Removing the material layers is performed by a directional substrative method, such as sputtering using argon. Using these methods, not only is the material layers removed from the upper surface of the metal line at the base of the via, but similar material composition layers that are horizontally orientated are also removed from the upper level metal lines. For example, removing the barrier/seed layers from the metal line at the first metal line level (Mx) in prior methods, also removes the barrier/seed layers from the horizontally orientated dielectric surfaces corresponding to the metal lines of the upper meta line levels, such as the third metal line level (Mx+2). Removing the barrier/seed layer from the trench surfaces for the metal lines prior to depositing the metal fill for providing the metal lines within the trenches reduces the reliability of the device. Removing the barrier layer allows for the metal of the metal lines to diffuse into the surrounding dielectric material.

The methods and structures described herein introduce a metal etch stop layer 200 between the upper metal line level layer (Mx+2) and the underlying upper via level layer (Vx+1), in which the metal etch stop layer 200 protects the dielectric 20 corresponding to the metal lines 25 during the etch processes that remove the barrier/seed layers 12, 13 at the base of the via 100. The metal etch stop layer 200 can also provide a diffusion barrier for the upper metal lines 25.

The via 100 has a small width W1. For example, the width W1 of base of the via 100 at the interface of the base of the via 100 with the upper surface of the metal line 5 in the first metal layer Mx may range from 5 nm to 50 nm. In some embodiments, the via 100 has a small width W1 at the interface with the metal line 5 that ranges from 10 nm to 30 nm.

The structure depicted in FIG. 1 provides one embodiment of a semiconductor interconnect that can be formed using a dual damascene process. In some embodiments, the via 100 may be a “super-via” or “skip-via” with no barrier/liner being present at the bottom of the via 100. In some embodiments, a low resistance cobalt or ruthenium liner may be present at the interface of the via 100 and the metal line 5 in the first metal line level (Mₓ). The via 100 may have a high aspect ratio being greater than 13, which in some instances can be as great as 100. When the structure employs multiple trenches for the metal lines, the trenches can each have the same depth regardless of the trench width.

In some embodiments, for a metal etch stop layer 200 having at thickness of 2 nm or less, and a via 100 having a height on the order of 40 nm, the capacitance impact can be on the order 1% to 2%, which can be negligible. The etch stop layer 200 may be easily integrated into back end of the line (BEOL) structures.

FIGS. 2-11 illustrate one embodiment for forming a skip via 100 with a liner/barrier-less via bottom. Referring to FIG. 2, an initial structure 300 is depicted that can include three metal line levels, e.g., a first metal line level (Mx), a second metal line level (Mx+1), and a third metal line level (Mx+2). A first via level (Vx) is present between the first metal line level (Mx) and the second metal line level (Mx+1). A second via level (Vx+1) is present between the third metal line level (Mx+2) and a second metal line level (Mx+1). The dielectric material in each of the metal line levels and the via line levels can be composed of low-k dielectric material, such as carbon doped silicon, e.g., SiOCH. It is noted that any of the dielectric materials described with reference to FIG. 1 may be employed for the composition of the dielectric layers depicted in FIG. 2. Referring to FIG. 2, atop each of the metal line levels (Mx, Mx+1, Mx+2) is a dielectric cap 11. The dielectric cap 11 may be composed of silicon carbon nitride (SiCN). Each of the dielectric material layers depicted in FIG. 2 may be formed using a deposition process, such as chemical vapor deposition (CVD).

A first region 305 of the initial structure 300 is processed to provide a super-via or skip via 100. A second region 310 of the initial structure 300 is processed to provide a metal line and via in each of the levels. In the second region 310 each via 302, 303 extends across a single dielectric layer, e.g., the dielectric layer in the first via level (Vₓ) and the dielectric layer in the second via level (Vₓ₊₁).

The second region 310 of the initial structure may include a first metal line 301 that is present in the first metal line level (Mₓ), a second metal line 304 present in the second metal line level (Mₓ₊₁), and a third metal line 306 that is present in the third metal line level (Mₓ₊₂). The second metal line 305 in the third metal line level (Mx+2) is connected to a second metal line 304 in the second metal line level (Mₓ₊₁) by a second via 303 that extends through an entirety of the second via level (Vₓ₊₁). The second metal line 304 in the second metal line level (Mₓ₊₁) is connected to a first metal line 301 in the first metal line level (Mₓ) by a first via 302 that extends through an entirety of the first via level (V_{X}). In the second region 310 each via 302, 303 extends across a single dielectric layer, e.g., the dielectric layer in the first via level (V_{X}) and the dielectric layer in the second via level (Vₓ₊₁).

The vias 302, 303, and metal lines 301, 304, 306 may have an electrically conductive fill that is copper.

In some embodiments, the sidewalls and base of each of the metal lines 301, 304, 306 and vias 302, 303 may include a barrier layer 31, such as tantalum nitride (TaN), that is in direct contact with the dielectric material that provides the sidewalls and base for each of the metal lines 301, 304, 306 and vias 302, 303. It is noted that tantalum nitride (TaN) is only one example of a composition for the barrier layer 31. Any of the aforementioned examples of the barrier layers 12 that are described with reference to FIG. 1 are applicable for the barrier layer 31 depicted in FIG. 2.

In some embodiments, an adhesion liner 32 is present on the barrier layer 31. The adhesion layer 32 may be composed of cobalt. It is noted that cobalt (Co) is only one example of a composition for the adhesion liner 32. Any of the aforementioned examples of the adhesion layers 13 that are described with reference to FIG. 1 are applicable for the adhesion layer 32 depicted in FIG. 2.

The first region 305 of the initial structure includes a metal line 5 in the first metal line level (Mx). The first region is processed to provide a via 100 consistent with the description of the super via or skip via that is provided with reference to FIG. 1. The metal line 5 may be composed of copper and may further includes a barrier metal layer 31 and an adhesion layer 32.

Still referring to FIG. 2, a stack 301 of interlevel dielectric layers (ILDs) 20, 29 and a metal etch stop layer 200 may then be formed atop the initial structure 300. The interlevel dielectric layers (ILDs) 20, 29 may be formed using a deposition process, such as chemical vapor deposition (CVD), and may be composed of a low-k dielectric material composition, such as carbon doped silicon, e.g., SiCOH. The metal etch stop layer 200 may be deposited using chemical vapor deposition, e.g., plasma enhanced chemical vapor deposition (PECVD), plating, electroplating, electroless plating or physical vapor deposition, e.g., sputtering. The metal etch stop layer 200 may be composed of a metal or metal nitride. For example, the metal etch stop layer 200 may be composed of tantalum (Ta) or tantalum nitride (TaN). In other examples, the metal etch stop layer 200 may include a plurality of different composition layers stacked upon one another. For example, the etch stop layer 200 may be composed of stacks of tantalum (Ta)/tantalum nitride (TaN), tantalum (Ta)/ruthenium (Ru), tantalum (Ta)/cobalt (Co), tantalum nitride (TaN)/ruthenium, tantalum nitride (TaN)/cobalt (Co), tantalum (Ta)/tantalum nitride (TaN)/ruthenium (Ru), and tantalum (Ta)/tantalum nitride (TaN)/cobalt (Co). The thickness of the metal etch stop layer 200 may have a thickness ranging from 1 nm to 5 nm. In some embodiments, the thickness of the metal etch stop layer 200 may range from 2 nm to 3 nm, in which at the lower endpoint higher etch resistance is desired, and at the upper endpoint lesser parasitic capacitance is desired.

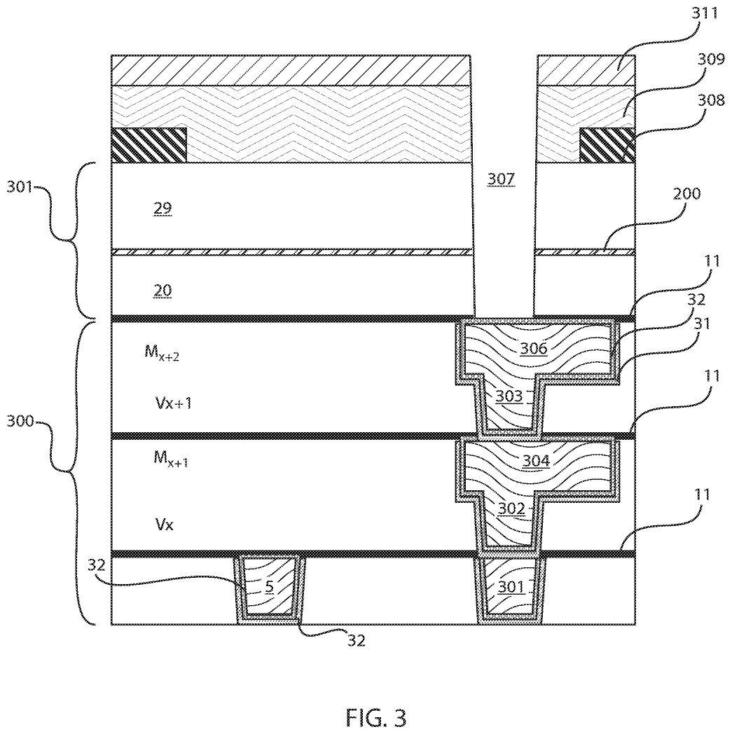

FIG. 3 illustrates one embodiment of forming an upper via opening 307 to the uppermost metal line 306 in the second region 310 of the initial structure 300. The process sequence for forming the upper via opening 307 may include forming a trench hardmask 308, depositing an organic planarization layer (OPL) material 309 filling the opening in the trench hardmask 308, and forming a first via hardmask 311. The trench hardmask 308 is patterned using photolithography and etch processes to provide dimensions for an etch mask for forming the trench for the metal line that is subsequently formed in the interlevel dielectric layer (ILD) layer 30 that is formed atop the metal etch stop layer 200. The opening in the trench hardmask 308 is filled with the material of the organic planarization layer 309, and the first via hardmask 311 may be formed atop the organic planarization layer 309. The organic planarization layer (OPL) 309 may be composed of an organic polymer that may include polyacrylate resin, epoxy resin, phenol resin, polyamide resin, polyimide resin, unsaturated polyester resin, polyphenylenether resin, polyphenylenesulfide resin, or benzocyclobutene (BCB).

The first via hardmask 311 may be patterned using photolithography and etch processes to provide dimensions for an etch mask for forming the via opening 307 to the uppermost metal line 306 in the second region 310 of the initial structure 300. The via opening 307 may be formed using an anisotropic etch process using the first via hardmask 311. The etch process may form the via opening 307 through the organic planarization layer 309, the upper interlevel dielectric layer 30, the metal etch stop layer 200 and the lower interlevel dielectric layer 20 stopping on the upper surface of the uppermost metal line 306. The etch process may be reactive ion etching (RIE) or ion sputtering.

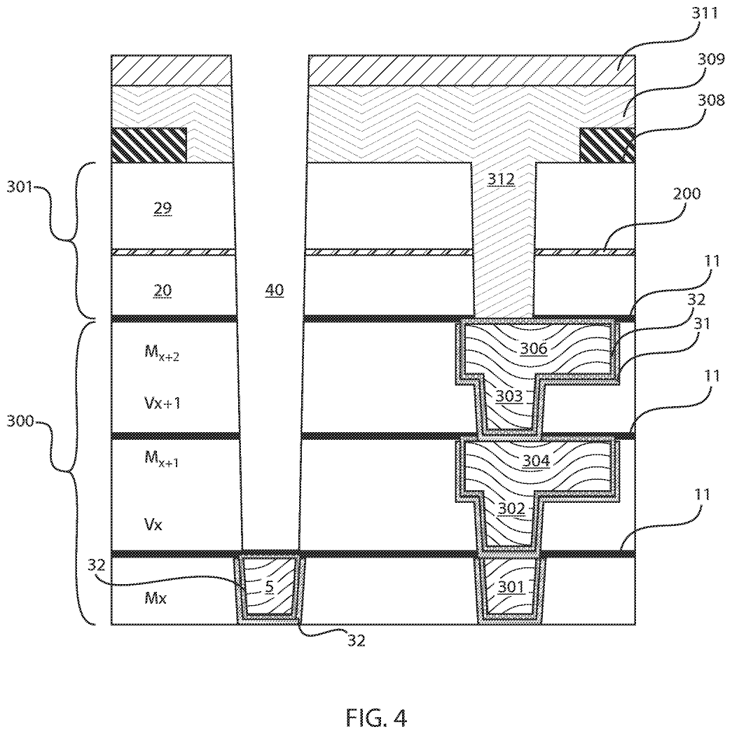

FIG. 4 illustrates one embodiment of patterning the via opening 40 for the via 100, e.g., super via or skip via, to the first metal line 5 in the first region 305 of the initial structure 300. Forming the via opening 40 may begin with depositing a sacrificial material 312 in the via opening 307 in the second region 310. Following filling the via opening 307 with the sacrificial 312, a second via hardmask 313 may be patterned using photolithography and etch processes to provide dimensions for an etch mask for forming the via opening 40 to the first metal line 5 in the first region 305 of the initial structure 300. The via opening 40 may be formed using an anisotropic etch process using the second via hardmask 313. The etch process may form the via opening 40 through the organic planarization layer 309, the upper interlevel dielectric layer 30, the metal etch stop layer 200, the lower interlevel dielectric layer 20, as well as each of the layers of the initial structure 300 stopping on one of the dielectric cap 11, the barrier layer 13 and the seed layer 12 present atop the first metal layer 5 in the first metal layer level (Mx). The etch process may be reactive ion etching (RIE) or ion sputtering.

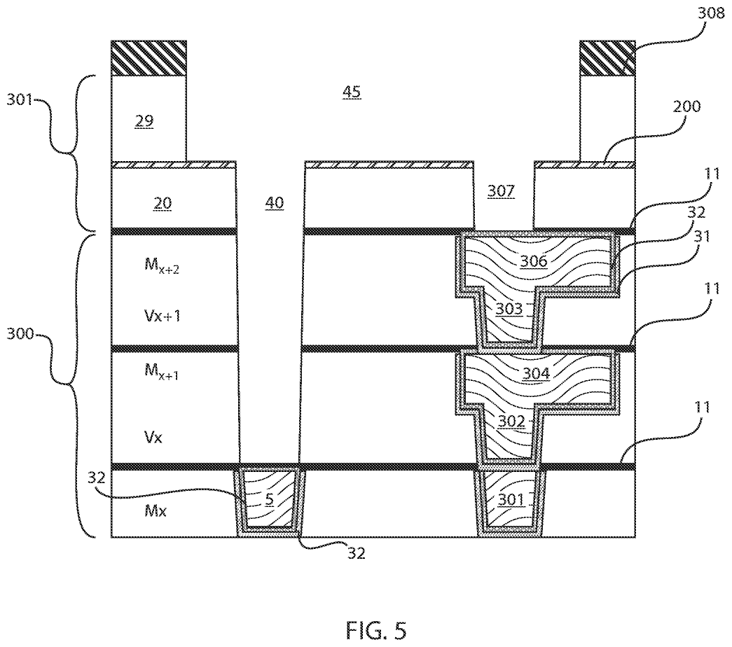

FIG. 5 illustrates forming the trench 45 for the upper metal line that is formed atop the metal etch stop layer 200. Forming the trench 45 can begin with removing the second via hardmask 313 and the organic planarization layer 309, and the fill material 312 in a process sequence that exposes the trench hardmask 308. Removal of the materials atop the trench hardmask 308 may be performed using a subtractive method, such as etching or planarization, e.g., chemical mechanical planarization (CMP). Following exposing the trench hardmask 308, the trench may be formed in the interlevel dielectric layer 30 that is present atop the metal etch stop layer 200 using an etch process that is selective to the etch stop layer 200. The etch process for forming the trench 45 may also remove the material of the organic planarization layer 309 and the fill material 312.

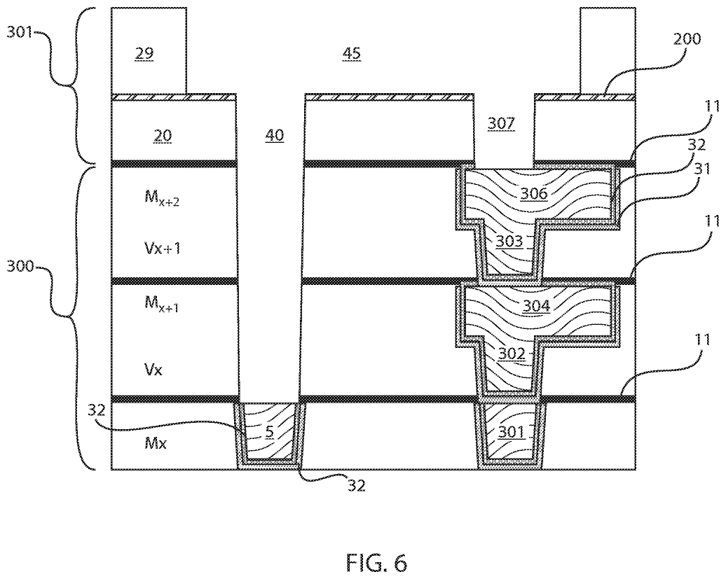

FIG. 6 illustrates one embodiment of removing the trench hardmask 308 and removing the material layers that are atop the first metal line 5 in the first metal line level (Mx) within the via opening 40 within the first region 305 of the initial structure 300. The material layers removed from the upper surface of the first metal line 5 can include any material layer that needs to be removed to expose the fill material, e.g., copper, of the first metal line 5, which can include at least one of the dielectric cap 11, the barrier layer 12 and the seed layer 13. The material layers that are atop the first metal line 5 in the first metal line level (Mx) within the via opening 40 within the first region 305 of the initial structure 300 can be removed using a directional process, such as ion beam sputtering. In other embodiments, the material layers that are atop the first metal line 5 in the first metal line level (Mx) within the via opening 40 within the first region 305 of the initial structure 300 can be removed using a directional etch process, such as reactive ion etching. It is noted that in some embodiments, the barrier layer 12, seed layer 13 and dielectric cap 11 may also be removed from the upper surface of the metal line 305 within the first via opening 307 during this stage of the process. It is noted that the metal etch stop layer 200 protects the underlying interlevel dielectric layer 20 during the substrative methods that are practiced at this stage of the manufacturing flow.

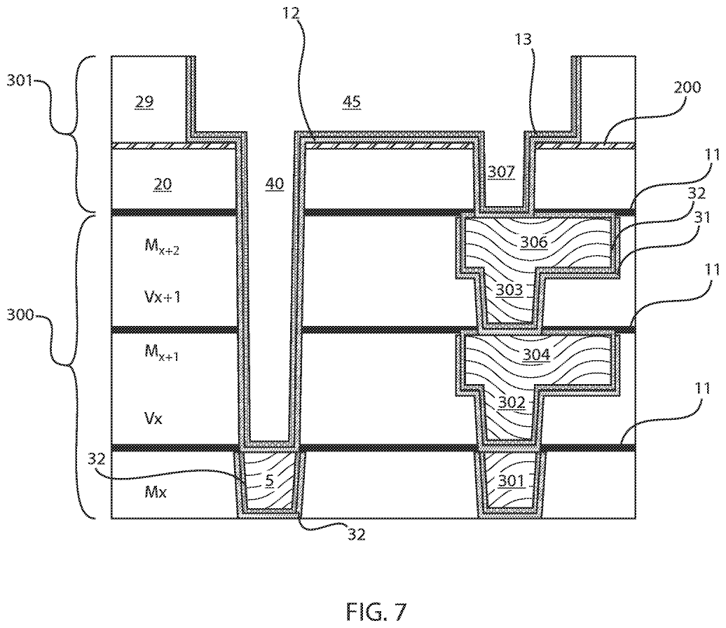

FIG. 7 depicts one embodiment of depositing a barrier liner 12 and seed liner 13 on the sidewalls and base of the trench 45 and the sidewalls and base of the vias 40, 307. The barrier liner 12 and the seed liner 13 may be conformally deposited layers. The term “conformal” denotes a layer having a thickness that does not deviate from greater than or less than 30% of an average value for the thickness of the layer.

In some embodiments, the barrier liner 12 and the seed liner 13 may be deposited using a deposition process, such as chemical vapor deposition, e.g., PECVD, or atomic layer deposition (ALD). In one embodiment, the barrier liner 12 may be composed of tantalum nitride (TaN). However, it is noted that the barrier liner 12 depicted in FIG. 7 may be composed of any of the metal and/or metal containing layers that have been described for the barrier liner 12 that has been described above with reference to FIG. 1. In one embodiment, the seed liner 13 can be composed of cobalt, ruthenium or a combination of cobalt and ruthenium layers. It is noted that the seed liner 13 is optional and may be omitted. The barrier liner 12 has been blanket deposited and is present in direct contact with the metal etch stop layer 200 that provides the base of the metal line trench 45, and the metal etch stop layer 200 is in direct contact with the electrically conductive fill material of the metal line 5 in the first metal line level (Mx).

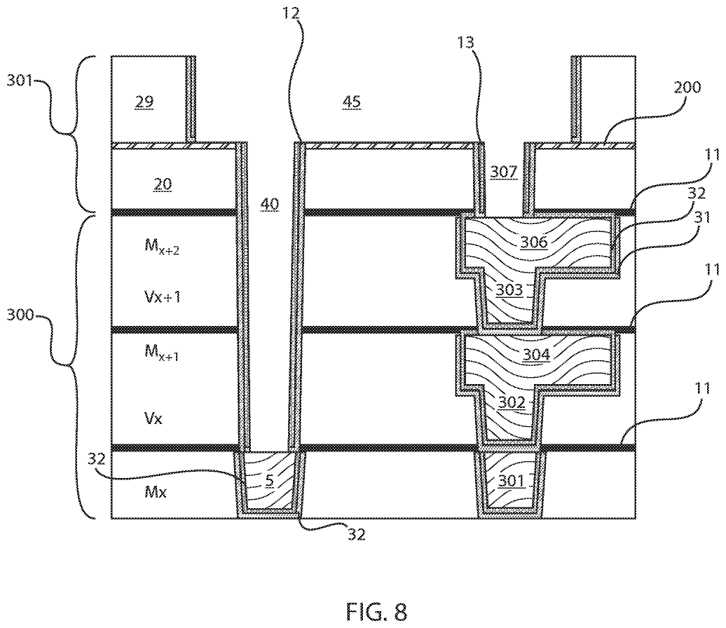

FIG. 8 illustrates one embodiment of a barrier liner 12 and/or adhesion liner 13 etch back process. The barrier liner 12 and/or adhesion liner 13 may be removed along all horizontally oriented surfaces by an anisotropic etch process. An “anisotropic etch process” denotes a material removal process in which the etch rate in the direction normal to the surface to be etched is greater than in the direction parallel to the surface to be etched. One form of anisotropic etching that is suitable for removing the barrier liner 12 and/or adhesion liner 13 is ion beam etching (IBE). Reactive ion etching (RIE) may also remove the barrier liner 12 and/or adhesion liner 13.

The anisotropic etch process depicted in FIG. 8 exposes the upper surface of the electrically conductive material, e.g., copper, that provides the fill for the first metal line 5. This provides a low resistance interface to the metal line 5, because the materials having a higher resistance than copper, e.g., tantalum nitride, have been removed from the interface. The anisotropic etch depicted in FIG. 8 also removed the barrier liner 12 and/or adhesion liner 13 from the base surfaces of the trench 45. As illustrated, the metal etch stop layer 200 is exposed by removing the barrier liner 12 and/or adhesion liner 13 from the base surfaces of the trench 45.

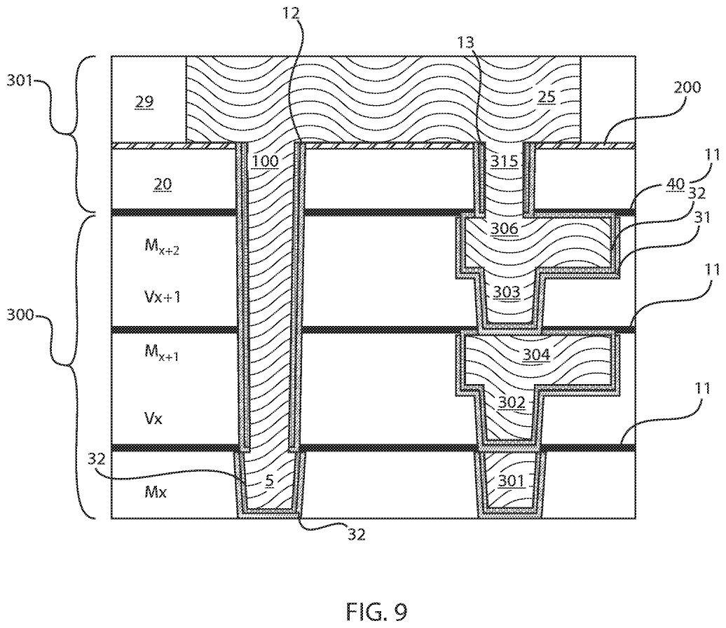

FIG. 9 illustrates a metal fill being applied to the trench 45 and via openings 40, 307. Depositing the metal fill produces the via 100, e.g., super via or skip via, to the first metal line 5 that is present in the first region 305 of the first metal line level Mx, the metal line 25 that is present in the trench 45, and the metal via 315 that is within the via opening to the metal line 306 to the uppermost metal line 25 in the second region 310 of the initial structure 300. The metal fill may be deposited using a plating process, such as plating, electroplating, electroless plating and combinations thereof. The metal fill can also be deposited using a deposition process, such as chemical vapor deposition (CVD), e.g., plasma enhanced chemical vapor deposition (PECVD).

As illustrated in FIG. 9, the metal fill for the via 100, e.g., super via or skip via, is formed is direct contact with the upper surface of the metal fill for the first metal line 5 in the first metal line level (Mx). The metal fill for the first metal line 5 and the metal fill for the via 100 may both be composed of copper (Cu). This provides that the metal fill for the via 100 directly contacts the metal fill for the first metal line 5 at the interface 150, which provides a low resistance interface. As illustrated in FIG. 9. The metal fill for the metal line 25 is deposited in direct contact with the metal etch stop layer 200, which provides the base of the trench 45.

Following deposition of the metal fill, a planarization process is applied to the structure, such as chemical mechanical planarization.

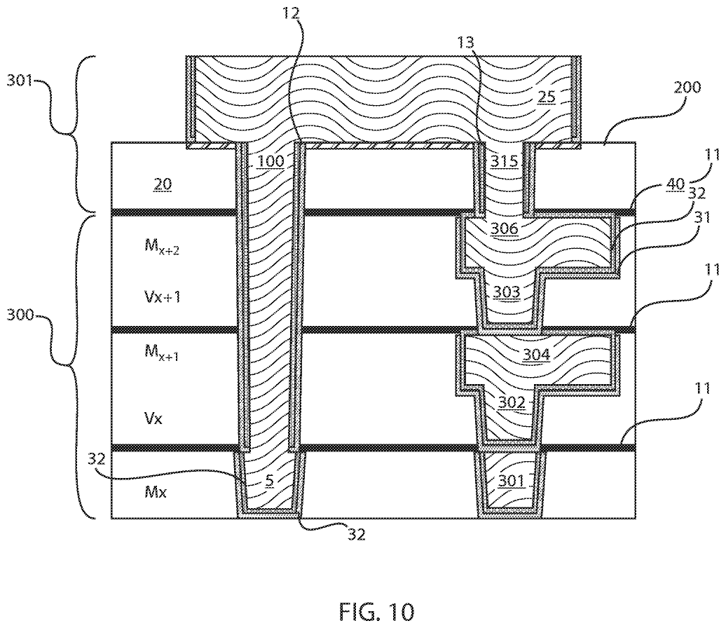

FIG. 10 illustrates removing the portion of the metal etch stop layer 200 that extends across the structure beyond the ends of the metal line 25. The electrical conductivity of the metal etch stop layer 200 can be the source of device electrical shorts. Therefore, the portions of the metal etch stop layer 200 that extend beyond the metal line 25 are removed.

First, the upper interlevel dielectric layer 29 is removed by an etch process that is selective to at least the metal fill of the metal line 25. In some embodiments, the etch process is also selective to the barrier liner 12. The etch process for removing the upper interlevel dielectric layer 30 may be a wet chemical etch or a dry etch. Removing the upper interlevel dielectric layer 29 exposes the portion of the metal etch stop layer 200 that extends beyond the end of the metal line.

FIG. 10 further illustrates removing the exposed portion of the metal etch stop layer 200 with an etch that is selective to the underlying interlevel dielectric layer 20. In some embodiments, etch may be a wet chemical etch or a dry etch, e.g., reactive ion etching.

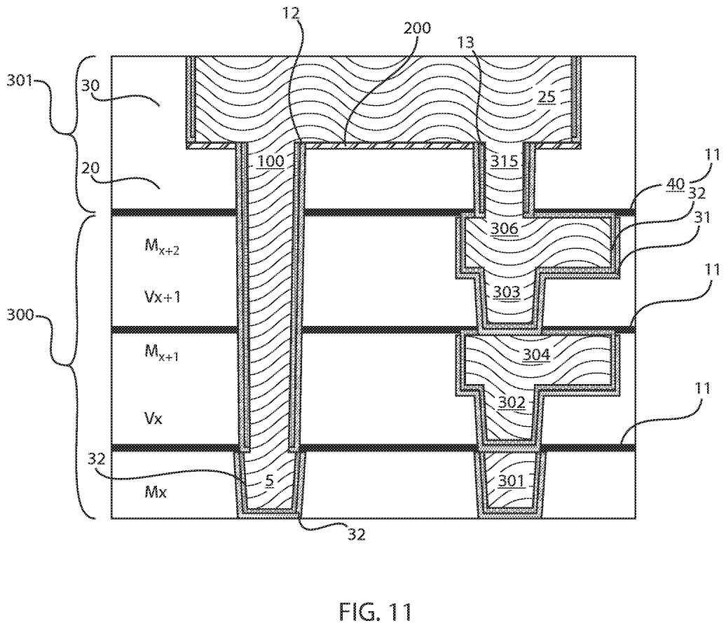

FIG. 11 illustrates a dielectric back fill process followed by planarization. Examples of dielectrics that can be used for the dielectric back fill 30 may be selected from the group consisting of diamond like carbon (DLC), organosilicate glass (OSG), fluorine doped silicon dioxide, carbon doped silicon dioxide, carbon doped silicon nitride, porous silicon dioxide, porous carbon doped silicon dioxide, boron doped silicon nitride, spin-on organic polymeric dielectrics (e.g., SILK™) spin-on silicone based polymeric dielectric (e.g., hydrogen silsesquioxane (HSQ), methylsilsesquioxane (MSQ), silicon boron carbon nitride (SiBCN), aluminum oxide, hafnium oxide, hafnium silicon oxide, hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, lead zinc niobate, nitrided hafnium silicate (HfSiON), lanthanum oxide (La₃O₂), lanthanum aluminate (LaAlO₃), zirconium silicate (ZrSiOₓ) and combinations thereof.

In one embodiment, the dielectric for the dielectric fill 30 is formed using a deposition method, such as a chemical vapor deposition (CVD) process, such as plasma enhanced chemical vapor deposition (PECVD), metal organic chemical vapor deposition (MOCVD) and/or low temperature chemical vapor deposition (LTCVD).

Following deposition, the dielectric back fill 30 is planarized so that the upper surface of the dielectric back fill 30 is coplanar with the upper surface of the metal line 25.

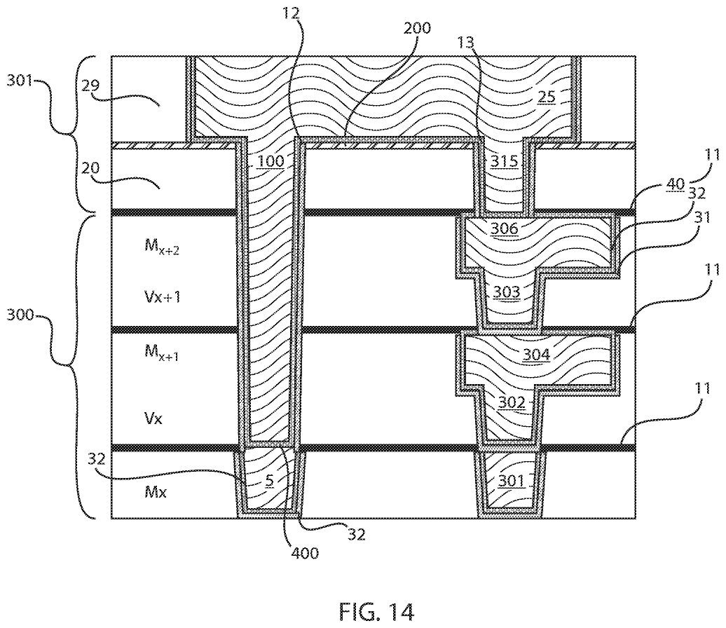

The process flow depicted in FIG. 2-11 illustrate only one embodiment of the present disclosure. It is not intended that the present disclosure be limited to only this example. For example, in another embodiment, a low-resistance liner 400 may be present at the interface of the base of the via 100, e.g., super via or skip via, and the upper surface of first metal line 5 in the first metal line level (Mx), as depicted in FIGS. 14-16. The low resistance liner 400 may be composed of a low resistance metal. Examples of low resistance metals that can be employed in the low resistance liner 400 can include cobalt (Co) and ruthenium (Ru). As illustrated in FIGS. 14-16, a portion of the low-resistance liner 400 is present at the interface 150 of the metal fill for the first metal line 5 and the metal fill for the base of the via 100.

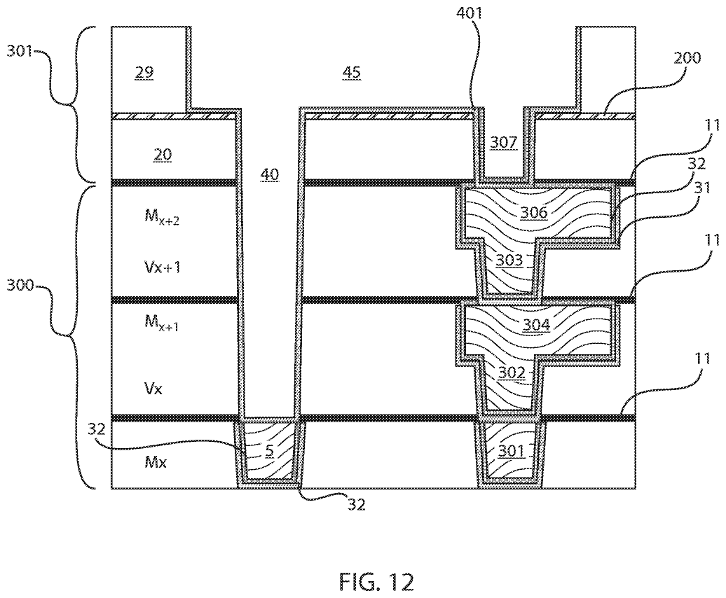

FIGS. 12-16 illustrate another embodiment for forming a super via or skip via, e.g., via 101. Beginning with the structure produced by the process flow illustrated in FIGS. 2-6, a barrier liner 401, e.g., barrier liner 401 composed of tantalum nitride (TaN), is conformally deposited on the sidewalls of the via opening 40 to the first metal line 5, as well as the trench opening 45, and the via opening 307 to the uppermost metal line 306 in the second region 310 of the initial structure 300, as depicted in FIG. 12. Although an example of a tantalum nitride (TaN) barrier liner 401 has been provided, the present disclosure is not limited to only this example, as any composition provided for the barrier liner 401 that has been described above for the barrier liner having reference number 12 in FIGS. 7-11.

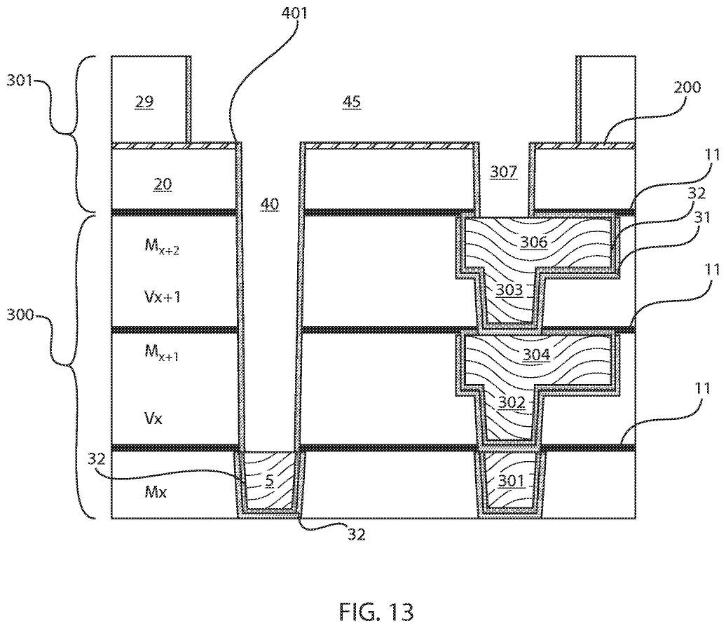

FIG. 13 illustrates a barrier etch back process. The barrier liner 401 may be removed along all horizontally oriented surfaces by an anisotropic etch process. One form of anisotropic etching that is suitable for removing the barrier liner 401 is ion beam etching (IBE). Reactive ion etching (RIE) may also remove the barrier liner 401.

The anisotropic etch process depicted in FIG. 13 exposes the upper surface of the electrically conductive material, e.g., copper, that provides the fill for the first metal line 5. The anisotropic etch depicted in FIG. 13 also removes the barrier liner 401 from the base surfaces of the trench 45. As illustrated, the metal etch stop layer 200 is exposed by removing the barrier liner 401 from the base surfaces of the trench 45.

FIG. 14 depicts one embodiment of a low-resistance liner 400 being deposited in the via openings 40, 307 and the trench 45, followed by forming the fill material for the vias 100, 315 and the metal line 25. As depicted in FIG. 14, the low resistance liner 400 may be present at the interface 150 of the base of the via 100, e.g., super via or skip via, and the upper surface of first metal line 5 in the first metal line level (Mx). The low resistance liner 400 may be composed of a low resistance metal. Examples of low resistance metals that can be employed in the low resistance liner 400 can include cobalt (Co) and ruthenium (Ru). As illustrated in FIGS. 14-16, a portion of the low-resistance liner 400 is present at the interface 150 of the metal fill for the first metal line 5 and the metal fill for the base of the via 100. By “low resistance” it can mean that the liner 400 has a resistance of 12×10⁻⁸Ω·m or less. For example, the liner 400 may be composed of ruthenium. Ruthenium has a resistance on the order of 11.5×10⁻⁸Ω·m. For example, the liner 400 may be composed of cobalt. Cobalt has a resistance on the order of 9×10⁻⁸Ω·m.

FIG. 14 further illustrates a metal fill being applied to the trench 45 and via openings 40, 307. Depositing the metal fill produces the via 100, e.g., super via or skip via, to the first metal line 5 that is present in the first region 305 of the first metal line level Mx, the metal line 25 that is present in the trench 45, and the metal via 315 that is within the via opening to the metal line 306 to the uppermost metal line 25 in the second region 310 of the initial structure 300. The metal fill may be deposited using a plating process, such as plating, electroplating, electroless plating and combinations thereof. The metal fill can also be deposited using a deposition process, such as chemical vapor deposition (CVD), e.g., plasma enhanced chemical vapor deposition (PECVD).

As illustrated in FIG. 14, the metal fill for the via 100, e.g., super via or skip via, is formed is direct contact with the low resistance liner 400. The metal fill for the first metal line 5 and the metal fill for the via 100 may both be composed of copper (Cu). This provides that the metal fill for the via 100 directly contacts the low resistance liner 400, and the low resistance liner 400 directly contacts the metal fill for the first metal line 5 at the interface 150, which provides a low resistance interface.

Following deposition of the metal fill, a planarization process is applied to the structure, such as chemical mechanical planarization.

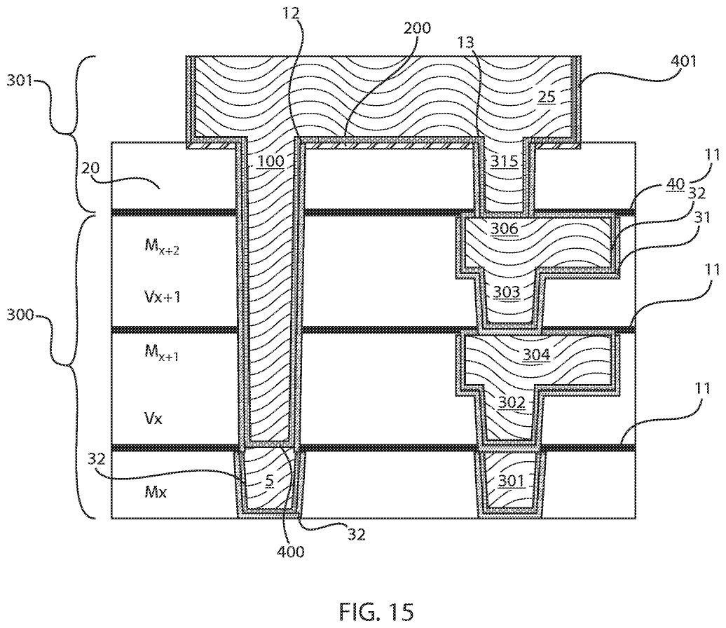

FIG. 15 illustrates removing the portion of the metal etch stop layer 200 that extends across the structure beyond the ends of the metal line 25. The electrical conductivity of the metal etch stop layer 200 can be the source of device electrical shorts. Therefore, the portions of the metal etch stop layer 200 that extend beyond the metal line 25 are removed.

First, the upper interlevel dielectric layer 29 is removed by an etch process that is selective to at least the metal fill of the metal line 25. In some embodiments, the etch process is also selective to the barrier liner 12. The etch process for removing the upper interlevel dielectric layer 30 may be a wet chemical etch or a dry etch. Removing the upper interlevel dielectric layer 29 exposes the portion of the metal etch stop layer 200 that extends beyond the end of the metal line.

FIG. 15 further illustrates removing the exposed portion of the metal etch stop layer 200 with an etch that is selective to the underlying interlevel dielectric layer 20. In some embodiments, etch may be a wet chemical etch or a dry etch, e.g., reactive ion etching.

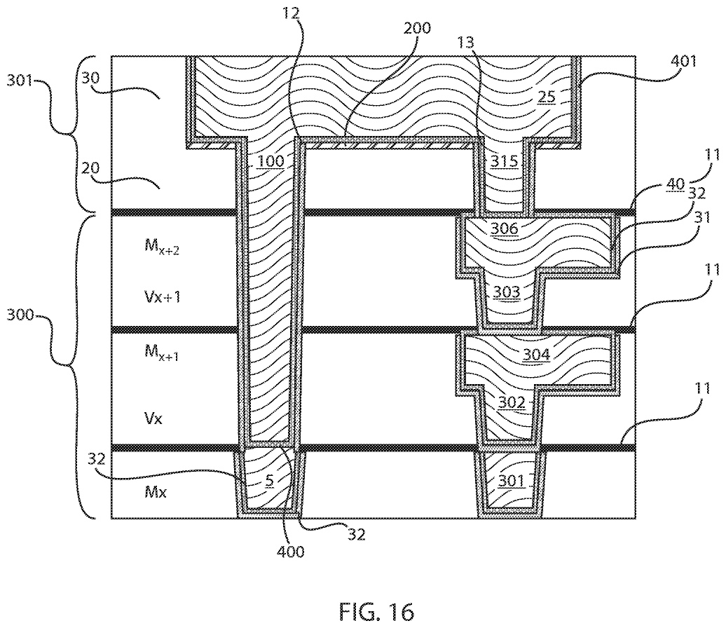

FIG. 16 illustrates a dielectric back fill process followed by planarization. Examples of dielectrics that can be used for the dielectric back fill 30 may be selected from the group consisting of diamond like carbon (DLC), organosilicate glass (OSG), fluorine doped silicon dioxide, carbon doped silicon dioxide, carbon doped silicon nitride, porous silicon dioxide, porous carbon doped silicon dioxide, boron doped silicon nitride, spin-on organic polymeric dielectrics (e.g., SILK™) spin-on silicone based polymeric dielectric (e.g., hydrogen silsesquioxane (HSQ), methylsilsesquioxane (MSQ), silicon boron carbon nitride (SiBCN), aluminum oxide, hafnium oxide, hafnium silicon oxide, hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, lead zinc niobate, nitrided hafnium silicate (HfSiON), lanthanum oxide (La₃O₂), lanthanum aluminate (LaAlO₃), zirconium silicate (ZrSiOₓ) and combinations thereof.

In one embodiment, the dielectric for the dielectric fill 30 is formed using a deposition method, such as a chemical vapor deposition (CVD) process, such as plasma enhanced chemical vapor deposition (PECVD), metal organic chemical vapor deposition (MOCVD) and/or low temperature chemical vapor deposition (LTCVD).

Following deposition, the dielectric back fill 30 is planarized so that the upper surface of the dielectric back fill 30 is coplanar with the upper surface of the metal line 25.

Having described preferred embodiments of a structure and method for forming a barrier liner free interface for metal via, it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

What is claimed is:

1. A method of forming an electrical communication structure comprising:
forming a metal etch stop layer in a material stack that includes a plurality of metal line levels, wherein a first metal line is present in the first metal line level of the plurality of metal line levels;
forming a via opening extending though the material stack to the first metal line in the first metal line level;
forming a trench in communication with the via opening in a dielectric layer of the material stack present on the metal etch stop layer;
forming a barrier liner on the via and the trench;
removing horizontal portions of the barrier liner at an interface of the via opening and the first metal line level and on the metal etch stop layer in the trench; and
filling the via opening and the trench with a metal fill, the metal fill in the via opening in direct contact with the first metal line, and the metal fill within the trench provides a second metal line in direct contact with the metal etch stop layer.

2. The method of claim 1, wherein the direct contact of the metal fill in the via to the first metal line is at the interface of the via opening and the first metal line level, and the metal etch stop layer is a diffusion barrier for the second metal line.

3. The method of claim 1 further comprising removing portions of the metal etch stop layer that extend past ends of the second metal line.

4. The method of claim 1, wherein the via opening has a base width dimension ranging from 5 nm to 50 nm at the interface of the via opening and the first metal line level.

5. The method of claim 1, wherein the via opening has an aspect ratio of 13 or greater.

6. The method of claim 1, wherein the metal fill within the via forms a skip via that is in direct contact with the first metal line and the second metal line, wherein the skip via extends through at least one intermediate metal line level without contacting an intermediate metal line within intermediate metal line level.

7. The method of claim 1, wherein the removing of the horizontal portions of the barrier liner at the interface of the via opening and the first metal line level and on the metal etch stop layer in the trench comprises ion beam etching.

8. The method of claim 1, wherein the metal etch stop layer is composed of a metal containing composition selected from the group consisting of tantalum, tantalum nitride and combinations thereof.

9. The method of claim 1, wherein the metal etch stop layer is composed of a multilayered stack selected from the group consisting of tantalum (Ta)/tantalum nitride (TaN), tantalum (Ta)/ruthenium (Ru), tantalum (Ta)/cobalt (Co), tantalum (Ta)/tantalum nitride (TaN)/ruthenium (Ru), tantalum (Ta)/tantalum nitride (TaN)/cobalt (Co) and combinations thereof.

10. The method of claim 1, further comprising forming a low resistance liner at the interface of the via opening and the first metal line level before filling the via opening, the low resistance liner having a metal composition selected from the group consisting of cobalt, ruthenium and combinations thereof.

11. An electrical communication structure comprising:
a plurality of metal line levels;
a first metal line in a first metal line level of the plurality of line levels;
a second metal line in an upper metal line level of the plurality of line levels, wherein a base of the second metal line is atop a metal etch stop layer that is aligned with edges of the second metal line; and
a via extend from the first metal line to the second metal line through the plurality of line levels, wherein the via is not in electrical communication with an intermediate metal line within the plurality of line levels between the first metal line level and the upper metal line level, the via having a via metal fill that is in direct contact with a metal line fill of the first metal line.

12. The electrical communication structure of claim 11, wherein the via has an aspect ratio of 13 or greater.

13. The electrical communication structure of claim 11, wherein the via has a width at an interface with the first metal line ranging from 5 nm to 50 nm.

14. The electrical communication structure of claim 11, wherein the metal etch stop layer has a composition selected from the group consisting of tantalum (Ta), tantalum nitride (TaN), tantalum (Ta)/tantalum nitride (TaN), tantalum (Ta)/ruthenium (Ru), tantalum (Ta)/cobalt (Co), tantalum (Ta)/tantalum nitride (TaN)/ruthenium (Ru), tantalum (Ta)/tantalum nitride (TaN)/cobalt (Co) and combinations thereof.

15. The electrical communication structure of claim 11 further comprising a metal nitride diffusion barrier on sidewalls of the via, wherein the metal nitride diffusion barrier is not present at the interface of a via metal fill and the metal line fill.

16. An electrical communication structure comprising:
a plurality of metal line levels;
a first metal line in a first metal line level of the plurality of line levels;
a second metal line in an upper metal line level of the plurality of line levels, wherein a base of the second metal line is atop a metal etch stop layer that is aligned with edges of the second metal line; and
a via extending from the first metal line to the second metal line through the plurality of line levels, wherein the via is not in electrical communication with an intermediate metal line within the plurality of line levels between the first metal line level and the upper metal line level, and the via further includes a low resistance liner at an interface of a via metal fill for the via and a metal line fill for the first metal line.

17. The electrical communication structure of claim 16, wherein the low resistance liner has a resistance of 12×10⁻⁸Ω·m or less.

18. The electrical communication structure of claim 16, wherein the low resistance liner has a composition selected from the group consisting of cobalt, ruthenium and combinations thereof.

19. The electrical communication structure of claim 16, wherein the metal etch stop layer has a composition selected from the group consisting of tantalum (Ta), tantalum nitride (TaN), tantalum (Ta)/tantalum nitride (TaN), tantalum (Ta)/ruthenium (Ru), tantalum (Ta)/cobalt (Co), tantalum (Ta)/tantalum nitride (TaN)/ruthenium (Ru), tantalum (Ta)/tantalum nitride (TaN)/cobalt (Co) and combinations thereof.

20. The electrical communication structure of claim 16 further comprising a metal nitride diffusion barrier on sidewalls of the via, wherein the metal nitride diffusion barrier is not present at the interface of a via metal fill and the metal line fill.
